(19) United States
(12) Patent Application Publication
(10) Pub. No.: US 2014/0339661 A1
(43) Pub. Date: Nov. 20, 2014

(54) METHOD TO MAKE MRAM USING OXYGEN ION IMPLANTATION

(71) Applicant: Yimin Guo, San Jose, CA (US)

(72) Inventor: Yimin Guo, San Jose, CA (US)

(73) Assignee: T3MEMORY, INC., Saratoga, CA (US)

(21) Appl. No.: 14/273,501

(22) Filed: May 8, 2014

Related U.S. Application Data
(60) Provisional application No. 61/825,102, filed on May 20, 2013.

(51) Int. Cl. H01L 43/10; H01L 43/08

(52) U.S. Cl. CPC H01L 43/10; H01L 43/08
USPC 257/421

(57) ABSTRACT

A method to make magnetic random access memory (MRAM), in particular, perpendicular spin transfer torque MRAM or p-STT-MRAM is provided. Electrically isolated memory cell is formed by ion implantation instead of etching and dielectric refill. Oxygen ion implantation is used to convert the photolithography exposed areas into metal oxide dielectric matrix. An ultra thin single-layer or multiple-layer of oxygen-getter, selected from Mg, Zr, Y, Th, Ti, Al, Ba is inserted into the active magnetic memory layer in addition to putting a thicker such material above and below the memory layer to effectively capture the impinged oxygen ions. Oxygen is further confined within the core device layer by adding oxygen stopping layer below the bottom oxygen-getter. After a high temperature anneal, a uniformly distributed and electrically insulated metal oxide dielectric is formed across the middle device layer outside the photolithography protected device area, thus forming MRAM cell without any physical deformation and damage at the device boundary.

### RELATED APPLICATIONS

This application claims the priority benefit of U.S. Provisional Application No. 61/825,102 filed on May 20, 2013, which is incorporated herein by reference.

### BACKGROUND OF THE INVENTION

1. Field of the Invention

This invention relates generally to spin-electronic devices, more particularly to a magnetic random access memory and a method to make the same using oxygen ion implantation.

2. Description of the Related Art

Magnetoresistive elements having magnetic tunnel junctions (also called MTJs) have been used as magnetic sensing elements for years. In recent years, magnetic random access memories (hereinafter referred to as MRAMs) using the magnetoresistive effect of MTJ have been drawing increasing attention as the next-generation solid-state nonvolatile memories that can cope with high-speed reading and writing, large capacities, and low-power-consumption operations. A ferromagnetic tunnel junction has a three-layer stack structure formed by stacking a recording layer having a changeable magnetization direction, an insulating spacing layer, and a fixed layer that is located on the opposite side from the recording layer and maintains a predetermined magnetization direction.

As a write method to be used in such magnetoresistive elements, there has been suggested a write method (spin torque transfer switching technique) using spin momentum transfers. According to this method, the magnetization direction of a recording layer is reversed by applying a spin-polarized current to the magnetoresistive element. Furthermore, as the volume of the magnetic layer forming the recording layer is smaller, the injected spin-polarized current to write or switch can be also smaller. Accordingly, this method is expected to be a write method that can achieve both device miniaturization and lower currents.

Further, as in a so-called perpendicular MTJ element, both two magnetization films have easy axis of magnetization in a direction perpendicular to the film plane due to their strong magnetic crystalline anisotropy, shape anisotropies are not used, and accordingly, the device shape can be made smaller than that of an in-plane magnetization type. Also, variance in the easy axis of magnetization can be made smaller. Accordingly, by using a material having a large magnetic crystalline anisotropy, both miniaturization and lower currents can be expected to be achieved while a thermal disturbance resistance is maintained.

There has been a known technique for achieving a high MR ratio in a perpendicular magnetoresistive element by forming a crystallization acceleration film that accelerates crystallization and is in contact with an interfacial magnetic film having an amorphous structure. As the crystallization acceleration film is formed, crystallization is accelerated from the tunnel barrier layer side, and the interfaces with the tunnel barrier layer and the interfacial magnetic film are matched to each other. By using this technique, a high MR ratio can be achieved. However, where a MTJ is formed as a device of a perpendicular magnetization type, the materials of the recording layer typically used in an in-plane MTJ for both high MR and low damping constant as required by low write current application normally don't have enough magnetic crystalline anisotropy to achieve thermally stable perpendicular magnetization against its demagnetization field. In order to obtain perpendicular magnetization with enough thermal stability, the recording layer has to be ferromagnetic coupled to additional perpendicular magnetization layer, such as TbCoFe, or CoPt, or multilayer such as (Co/Pt)n, to obtain enough perpendicular anisotropy. Doing so, reduction in write current becomes difficult due to the fact that damping constant increases from the additional perpendicular magnetization layer and its associated seed layer for crystal matching and material diffusion during the heat treatment in the device manufacturing process.

In a spin-injection MRAM using a perpendicular magnetization film, a write current is proportional to the perpendicular anisotropy, the damping constant and inversely proportional to a spin polarization, and increases in proportional to a square of an area size. Therefore, reduction of the damping constant, increase of the spin polarization and reduction of an area size are mandatory technologies to reduce the write current.

Besides a write current, the stability of the magnetic orientation in a MRAM cell as another critical parameter has to be kept high enough for a good data retention, and is typically characterized by the so-called thermal factor which is proportional to the perpendicular anisotropy as well as the volume of the recording layer cell size. Although a high perpendicular anisotropy is preferred in term of a high thermal disturbance resistance, an increased write current is expected as a cost.

To record information or change resistance state, typically a recording current is provided by its CMOS transistor to flow in the stacked direction of the magnetoresistive element, which is hereinafter referred to as a “vertical spin-transfer method.” Generally, constant-voltage recording is performed when recording is performed in a memory device accompanied by a resistance change. In a STT-MRAM, the majority of the applied voltage is acting on a thin oxide layer (tunnel barrier layer) which is about 10 angstroms thick, and, if an excessive voltage is applied, the tunnel barrier breaks down. More, even when the tunnel barrier does not immediately break down, if recording operations are repeated, the element may still become nonfunctional such that the resistance value changes (decreases) and information readout errors increase, making the element un-recordable. Furthermore, recording is not performed unless a sufficient voltage or sufficient spin current is applied. Accordingly, problems with insufficient recording arise before possible tunnel barrier breaks down.

In the mean time, since the switching current requirements reduce with decreasing MTJ element dimensions, STT-MRAM has the potential to scale nicely at even the most advanced technology nodes. However, patterning of small MTJ element leads to increasing variability in MTJ resistance and sustaining relatively high switching current or recording voltage variation in a STT-MRAM.

Reading STT MRAM involves applying a voltage to the MTJ stack to discover whether the MTJ element states at high resistance or low. However, a relatively high voltage needs to be applied to the MTJ to correctly determine whether its resistance is high or low, and the current passed at this voltage leaves little difference between the read-voltage and the write-voltage. Any fluctuation in the electrical characteristics of individual MTJs at advanced technology nodes could cause what was intended as a read-current, to have the effect of a write-current, thus reversing the direction of magnetization of the recording layer in MTJ. Majorities of cell-to-cell variations come from the MTJ cell patterning process.

The MTJ patterning process becomes one of the most challenging aspects of manufacturing. Conventional techniques utilized to pattern small dimensions in a chip, such as ion milling etching (IBE) or reactive ion etching (RIE), having been less than satisfactory when applied to magnetic tunnel junction stacks used for MRAM. In most cases when these techniques are used, it is very difficult or almost impossible to cleanly remove etched materials without partial damages to magnetic tunnel junction properties and electric current shunting. In a RIE etching of magnetic material, physical sputtering is still the major component which unavoidable results in the formation of re-deposited residues that can short circuit the junctions of the MTJ or create shunting channel of the MTJ, yielding high resistance variations and serious reliability issues.

Another problem of conventional patterning techniques is the degradation of the recording layer and reference layer in the MTJ, due to corrosion caused by chemical residue remaining after etching. Exposure to reactive gases during refilling deposition of dielectrics such as silicon dioxide or silicon nitride after the MTJ etching can also cause corrosion. After refilling of dielectric material, a chemical mechanic polishing process is required to smooth out the top surface for bit line fabrication, which introduces a big manufacturing challenging as well as high cost and further corrosion.

Thus, it is desirable to provide a greatly improved method or innovative method that enables well-controllable and low cost fabrication in MTJ patterning while eliminating damage, degradation and corrosion.

The conventional fabrication method to form STT-MRAM is by etching and dielectric refilling. Due to a weaker ion bombardment during etch at the lower portion of the MTJ pillar; the sensor profile is typically sloped with narrow top and wide bottom. As the result, the formed sensor size cannot be made small enough to reduce the write current to switch the memory layer. Also, due to the non-volatile nature of the etched magnetic materials, often the etched sensor edge got damaged with electrical shorting across the MgO barrier.

In our earlier invention (patent application Ser. No. 14/251,576), we use an ion implantation method to add oxygen ions into the magnetic memory layer in the area exposed by photolithography patterning. A typical film stack contains six core layers (FIG. 1): an ion-stopping layer (110) at the bottom, two oxygen getters (120 & 140) sandwich the middle magnetic layer (130), an ion-capping layer (150), and an ion-mask layer (160).

### BRIEF SUMMARY OF THE PRESENT INVENTION

The present invention is about a method to make magnetic random access memory (MRAM), in particular, perpendicular spin transfer torque MRAM or p-STT-MRAM. Electrically isolated memory cell is formed by ion implantation instead of etching and dielectric refill. Oxygen ion implantation is used to convert the photolithography exposed areas into metal oxide dielectric matrix. An ultra thin single-layer or multiple-layer of oxygen-getter, selected from Mg, Zr, Y, Th, Ti, Al, Ba is inserted into the active magnetic memory layer in addition to putting a thicker such material above and below the memory layer to effectively capture the impinged oxygen ions. Oxygen is further confined within the core device layer by adding oxygen stopping layer below the bottom oxygen-getter. After a high temperature anneal, a uniformly distributed and electrically insulated metal oxide dielectric is formed across the middle device layer outside the photolithography protected device area, thus forming MRAM cell without any physical deformation and damage at the device boundary.

### BRIEF DESCRIPTION OF THE DRAWINGS

FIG. 1 Prior art (our early patent application).

FIG. 3 Ion mask is formed after photolithography patterning and etch.

FIG. 4 Oxygen ions are implanted into the desired region.

FIG. 5 Ion capping layer is removed from the exposed region.

FIG. 6 Device after dielectric refill and CMP.

FIG. 7 Device after a top metallic lead is formed.

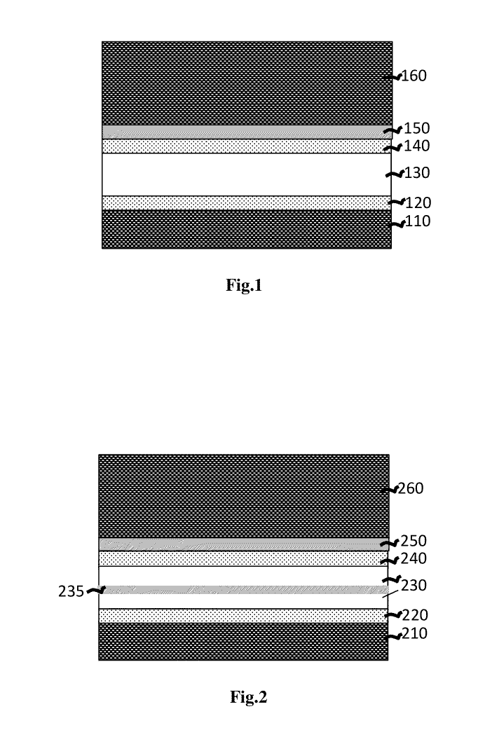

### DETAILED DESCRIPTION OF THE INVENTION

Similar to the earlier invention, our memory device still contains five core film stacks (FIG. 2): an ion-stopping layer at the bottom (210), two oxygen getters (220 & 240) sandwich the middle magnetic layer magnetic memory layer (230), an ion-capping layer (250), and an ion-mask layer (260).

To better capture the oxygen ions implanted in the memory region, thus forming a uniformly distributed metal oxide dielectric (230 in FIG. 2) in the photolithography exposed area outside the device, we add an ultra thin oxygen-getter layer (235 in FIG. 2) into the middle magnetic layer. Such oxygen getter is selected from Mg, Zr, Y, Th, Ti, Al, Ba, with Mg as a preferred material due to its close MgO crystalline lattice match with the memory material. The thickness of such oxygen-getter layer must be thin enough (<3 A) so that the magnetic integrity of each of these magnetic (memory and reference) layers is not affected. We often call such a thin oxygen getter layer as a dusting layer. If needed, a multiple dusting layers can be added in the thickness magnetic layer (230).

The ion-stopping layer (210) typically contains a heavy metal with large atomic number, selected from Hf, Ta, W, Re, Os, Ir, Pt, Au, with a thickness between 200 A-1000 A. Pt or Au is superior to other materials because of their resistance to oxygen oxidation. The oxygen getter layers (220 & 240) typically contain a material selected among Mg, Zr, Y, Th, Ti, Al, and Ba above and below the active device region (230) to effectively capture oxygen ions during oxygen ion implantation.

For magnetic random access memory application, Mg is preferred due to its MgO close lattice constant match with CoFe. The thickness of the oxygen getter (220, 240) is typically about 50 A-100 A. The device region (230), such as for perpendicular spin transfer torque memory random access memory (pSTT-MRAM), typically contains three key sub-layers: CoFeB memory layer with a thickness between 10 A-30 A, MgO dielectric tunneling layer with a thickness between 8-15 A, and a magnetic reference layer made from a hard magnetic materials, CoPt, CoPd, CoTb, FePt, FePd, FeTb or Co/Pt, Co/Pd, Fe/Pt, FePd multilayer with a total thickness between 30 A-80 A. The oxygen-getter dusting layer (235) can be added to the memory layer CoFeB and reference layer (CoPt) or even multiple dusting in the reference layer as long as such dusting no affect the magnetic integrity of these device layers.

The ion-capping layer (250) has two functions: first to prevent oxygen ions backing-off during oxygen ion implantation and, second to act as a reactive ion etch (RIE) stopping layer for the formation of the top ion-mask layer (260). The ion-capping layer can be selected from Ru, Cu, Al, and Cr with a thickness between 100 A-300 A. The top ion-mask layer (260), in general, uses the same material as the bottom ion-stopping layer (210), such as Hf, Ta, W, Re, Os, Ir, Pt, Au. For MRAM, Ta is preferred because of its ease in CF4 RIE process during the mask formation.

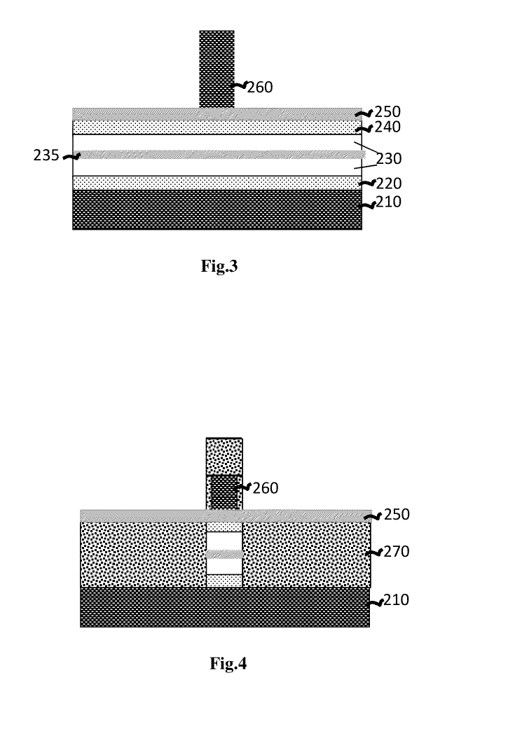

After the film deposition, a photolithography patterning is performed, which can be either one patterning or dual patterning and process (refer to our earlier dual pattern Patent application). The patterned wafer is then RIE etched to remove the exposed mask material. For Ta ion mask, typical etchant is CF4 or CF3H or other C,F,H containing gases. The etching is stopped on top of the ion-capping layer (250). Then oxygen plasma is used to remove the remaining photoresist and etchant re-dep. The formed ion-mask (260) is shown in FIG. 3.

Then immediately followed by an oxygen ion implantation to add oxygen into the device layer (230). Due to presence of ion stopping layer (210), oxygen ions are mainly captured by the three oxygen getter layers (220, 235 & 240) redistributed into the device layer (230) forming a new metal oxide dielectric layer (270) with an uniform oxygen re-distribution across it after a high temperature anneal. In the mean time, the top portion of the ion-mask layer (260) is also oxidized as shown in FIG. 4.

Then an etching process is used to remove the exposed portion of the ion-capping layer using CH3OH, or CO & NH4 to prevent electric shorting within the IC device. The etching is stopped on the top surface of oxide layer 270 (FIG. 5).

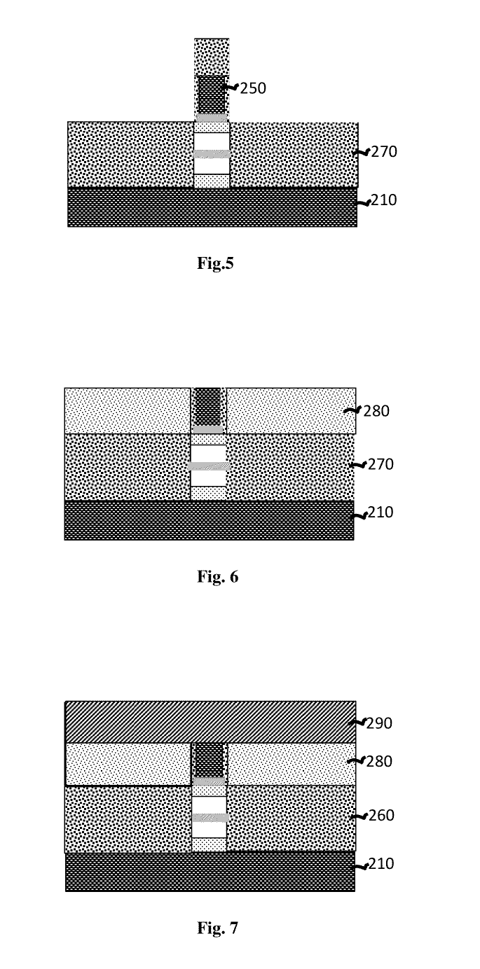

Then a dielectric SiO2, SiNx or Al2O3 layer (280) is refilled on the etched portion of the device and a chemical mechanic polishing (CMP) is used to flatten the wafer surface and also remove the top portion of the oxidized ion-mask layer (250) (see FIG. 6).

Then a top metallic film stack (290) is deposited and subsequently patterned to form top electrode (FIG. 7), which can be a single metallic layer of Ru, Cu, Al or alloy of them or sandwiched between two Ta layers, with a thickness of 500 to 1000 A.

The wafer is finally annealed at high temperature between 250 C to 500 C for a time between 30 sec to 30 minutes to activate the oxygen-metallic bonding for form metal oxide electrically insulating dielectric matrix and also to repair the damage from oxygen ion implantation.

1. An integrated circuit (IC) electronic device is made by oxygen ion implantation.

2. The element of claim 1, wherein said IC device is a spin transfer torque magnetic random access memory (STT-MRAM).

3. The element of claim 2, wherein said magnetic random access memory is a perpendicular spin torque transfer magnetic random access memory (pSTT-MRAM).

4. The element of claim 1, wherein said IC device contains an ion implantation stopping layer, an oxygen gettering layer, an active device layer, a second oxygen gettering layer and an ion-capping layer, and ion-mask layer.

5. The element of claim 4, wherein said ion implantation stopping layer is Ta, Hf, W, Re, Os, Ir, Pt, Au with a thickness between 200 A to 500 A, and Pt, and Au are superior for their oxidation resistance.

6. The element of claim 4, wherein said oxygen getter is Mg, Zr, Y, Th, Ti, Al, and Ba with a thickness between 20 A to 100 A, and Mg is preferred for MRAM device due to its MgO close lattice match with CoFe.

7. The element of claim 3, wherein said pSTT-MRAM contains a CoFeB memory layer with a thickness between 10-30 A, a MgO dielectric tunneling layer with a thickness between 8-15 A and magnetic reference layer of CoPt, CoPd, CoTb, FePt, FePd, FeTb or Co/Pt, Co/Pd, Fe/Pt, FePd multilayer with a total thickness between 30 A to 80 A.

8. The element of claim 7, wherein said pSTT-MRAM contains an ultra thin oxygen-getter layer inserted into each of these magnetic (memory and reference) layers, and the oxygen-getter layer is selected from Mg, Zr, Y, Th, Ti, Al, and Ba with a thickness less than 3 A.

9. The element of claim 8, wherein said inserted oxygen-getter layer will not affect the magnetic integrity of the two magnetic (memory and reference) layers.

10. The element of claim 4, wherein said ion-capping layer is Ru, Cu, Al, and Cr with a thickness between 100 A-300 A, and Ru is preferred.

11. The element of claim 4, wherein said IC device film stack is photolithography patterned.

12. The element of claim 11, wherein said exposed ion mask region in the patterned IC device is etched.

13. The element of claim 12, wherein said etched ion-mask is Ta and the etchant gas is CF4 or CF3H or other C,F,H containing gases. The etching is stopped on top of the ion-capping layer, and the remaining photoresist and redep is removed by oxygen burring.

14. The element of claim 13, wherein said patterned IC device undergoes oxygen ion implantation with certain ions dose and implanting energy to impinge the oxygen ions into the active device region, and the impinged oxygen ions are stopped by bottom ion-stopping layer.

15. The element of claim 14, wherein said impinged oxygen ions are captured by oxygen gettering layers below and above the device region.

16. The element of claim 15, wherein said oxygen ion-implanted device wafer is etched to remove the exposed ion-capping layer Ru using CH3OH, or CO & NH4 as etchant gas.

17. The element of claim 16, wherein said etched device wafer is refilled with SiO2, SiNx, or AlOx dielectrics, which is chemical-mechanical-polished to flatten the surface and remove the top portion of the oxidized ion-mask.

18. The element of claim 17, wherein said dielectric filled device wafer is deposited with a metallic electrode layer made of Ru, Cu, Al or alloy of them or sandwiched between two Ta layers, Ta/Ru/Ta or Ta/Cu&Al alloy/Ta, with a thickness of 500 to 1000 A.

19. The element of claim 18, wherein said top electrode layer is patterned and etched to form electrode line.

20. The element of claim 19, wherein said device wafer claimed above is high temperature annealed between 250 C to 500 C for 30 seconds to 30 minutes to activate the metal-oxide bonding and to repair the device damage during oxygen ion implantation.
